(19) United States
(12) Patent Application Publication
(10) Pub. No.: US 2019/0044538 A1
(43) Pub. Date: Feb. 7, 2019

(54) ESTIMATING CHANNEL ASYMMETRY FOR IMPROVED LOW-DENSITY PARITY CHECK (LDPC) PERFORMANCE

(71) Applicant: Intel Corporation, Santa Clara, CA (US)

(72) Inventors: Poovaiah PALANGAPPA, San Jose, CA (US); Ravi H. MOTWANI, Fremont, CA (US)

(21) Appl. No.: 15/943,607

(22) Filed: Apr. 2, 2018

(51) Int. Cl. H03M 13/11; G06F 11/10

(52) U.S. Cl. CPC H03M 13/1125; G06F 11/1048; G06F 11/1068

(57) ABSTRACT

Examples include techniques for improving low-density parity check decoder performance for a binary asymmetric channel. Examples include logic for execution by circuitry to decode an encoded codeword of data received from a memory using predetermined log-likelihood ratios (LLRs) to produce a decoded codeword, return the decoded codeword when the decoded codeword is correct, and repeat the decoding using the predetermined LLRs when the decoded codeword is not correct, up to a first number of times when the decoded codeword is not correct. When a correct decoded codeword is not produced using predetermined LLRs, further logic may be executed to estimate the LLRs, decode the encoded codeword using the estimated LLRs to produce a decoded codeword, return the decoded codeword when the decoded codeword is correct, and repeat the decoding using estimated LLRs when the decoded codeword is not correct, up to a second number of times when the decoded codeword is not correct.

### TECHNICAL FIELD

Examples described herein are generally related to techniques for improving performance of low-density parity check (LDPC) decoders in computing systems.

### BACKGROUND

Low-density parity check (LDPC) codes are a class of linear block error correcting codes (ECCs). The name comes from the characteristic of their parity check matrix which contains only a few 1's in comparison to the amount of 0's. Their main advantage is that they provide an error correction performance that is very close to the capacity for many different types of channels and linear time complex algorithms for decoding. Furthermore, they are suited for implementations that make heavy use of parallelism.

In some computing systems, LDPC codes are used for communication of data to and from memory devices. LDPC decoders lose significant error correcting performance due to asymmetry in the underlying channel, such as when interfacing with NAND flash memory and a type of non-volatile memory known as a 3-dimensional cross-point memory (commercially available as 3D XPoint™ from Intel Corporation). In other words, the channel is known to behave as a binary asymmetric channel, which could flip 1's to 0's and 0's to 1's (e.g., generating errors in the data being communicated) with unequal probabilities.

### BRIEF DESCRIPTION OF THE DRAWINGS

FIG. 1 illustrates an example first system.

FIG. 2 illustrates an example of a logic flow for managing decoding.

### DETAILED DESCRIPTION

Embodiments of the present invention improve the decoding capability of LDPC decoders in the presence of an asymmetrical channel (such as one coupled to a NAND memory or a 3-dimensional cross-point memory (e.g., 3D XPoint™ memory commercially available from Intel Corporation)). Embodiments of the present invention estimate cross-over probabilities (i.e., erroneous changes from 0 to 1 and from 1 to 0 in data bits), represented as log-likelihood ratios (LLRs), and leverage this information for improved min-sum decoding performance. Embodiments recover a majority of the performance that is lost by the decoder due to channel asymmetry, incur minimal area overhead since an existing min-sum infrastructure may be used for the estimation method, and has minimal-to-nil latency impact.

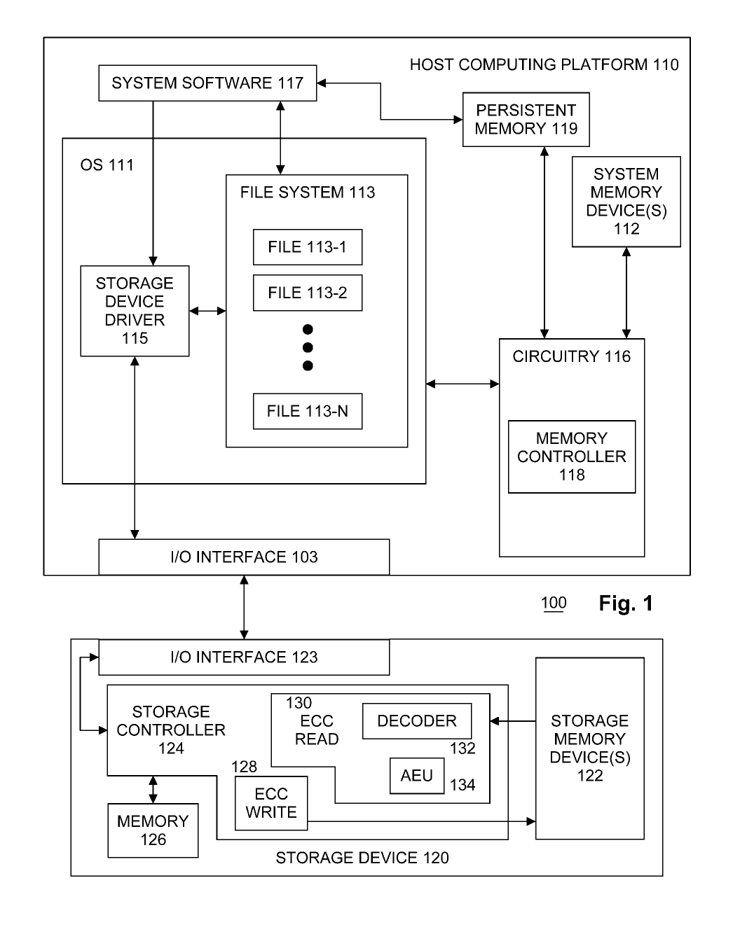

FIG. 1 illustrates an example first system 100. System 100 includes a host computing platform 110 coupled to one or more storage device(s) 120 through I/O interface 103 and I/O interface 123. Host computing platform 110 may include an operating system (OS) 111, one or more system memory device(s) 112, circuitry 116 and system software 117. For these examples, circuitry 116 may be capable of executing various functional elements of host computing platform 110 such as OS 111 and system software 117 that may be maintained, at least in part, within system memory device(s) 112. Circuitry 116 may include host processing circuitry to include one or more central processing units (CPUs) (not shown) and associated chipsets and/or controllers.

According to some examples, as shown in FIG. 1, OS 111 may include a file system 113 and a storage device driver 115 and storage device 120 may include a storage controller 124, one or more storage memory device(s) 122 and memory 126. OS 111 may be arranged to implement storage device driver 115 to coordinate at least temporary storage of data for a file from among files 113-1 to 113-n, where “n” is any whole positive integer >1, to storage memory device(s) 122. The data, for example, may have originated from or may be associated with executing at least portions of system software 117 and/or OS 111, or application programs (not shown in FIG. 1). As described in more detail below, OS 111 communicates one or more commands and transactions with storage device 120 to write data to and read data from storage device 120. The commands and transactions may be organized and processed by logic and/or features at the storage device 120 to write the data to and read the data from storage device 120.

In some examples, storage controller 124 may include logic and/or features to receive a read transaction request or a write transaction request to storage memory device(s) 122 at storage device 120. For these examples, the write transaction may be initiated by or sourced from system software 117 that may, in some embodiments, utilize file system 113 to write data to storage device 120 through input/output (I/O) interfaces 103 and 123. For these examples, the read transaction may be initiated by or sourced from system software 117 that may, in some embodiments, utilize file system 113 to read data from storage device 120 through input/output (I/O) interfaces 103 and 123.

In some examples, memory 126 may include volatile types of memory including, but not limited to, RAM, D-RAM, DDR SDRAM, SRAM, T-RAM or Z-RAM. One example of volatile memory includes DRAM, or some variant such as SDRAM. A memory subsystem as described herein may be compatible with a number of memory technologies, such as DDR4 (DDR version 4, initial specification published in September 2012 by JEDEC), LPDDR4 (LOW POWER DOUBLE DATA RATE (LPDDR) version 4, JESD209-4, originally published by JEDEC in August 2014), WIO2 (Wide I/O 2 (WideIO2), JESD229-2, originally published by JEDEC in August 2014), HBM (HIGH BANDWIDTH MEMORY DRAM, JESD235, originally published by JEDEC in October 2013), DDR5 (DDR version 5, currently in discussion by JEDEC), LPDDR5 (LPDDR version 5, currently in discussion by JEDEC), HBM2 (HBM version 2, currently in discussion by JEDEC), and/or others, and technologies based on derivatives or extensions of such specifications.

However, examples are not limited in this manner, and in some instances, memory 126 may include non-volatile types of memory, whose state is determinate even if power is interrupted to memory 126. In some examples, memory 126 may include non-volatile types of memory that is a block addressable, such as for NAND or NOR technologies. Thus, memory 126 can also include a future generation of types of non-volatile memory, such as a 3-dimensional cross-point memory (3D XPoint™), or other byte addressable non-volatile types of memory. According to some examples, memory 126 may include types of non-volatile memory that includes chalcogenide glass, multi-threshold level NAND flash memory, NOR flash memory, single or multi-level Phase Change Memory (PCM), a resistive memory, nanowire memory, FeTRAM, MRAM that incorporates memristor technology, or STT-MRAM, or a combination of any of the above, or other memory.

In some examples, storage memory device(s) 122 may be a device to store data from write transactions and/or write operations. Storage memory device(s) 122 may include one or more chips or dies having gates that may individually include one or more types of non-volatile memory to include, but not limited to, NAND flash memory, NOR flash memory, 3-D cross-point memory (3D XPoint™), ferroelectric memory, SONOS memory, ferroelectric polymer memory, FeTRAM, FeRAM, ovonic memory, nanowire, EEPROM, phase change memory, memristors or STT-MRAM. For these examples, storage device 120 may be arranged or configured as a solid-state drive (SSD). The data may be read and written in blocks and a mapping or location information for the blocks may be kept in memory 126.

According to some examples, communications between storage device driver 115 and storage controller 124 for data stored in storage memory devices(s) 122 and accessed via files 113-1 to 113-n may be routed through I/O interface 103 and I/O interface 123. I/O interfaces 103 and 123 may be arranged as a Serial Advanced Technology Attachment (SATA) interface to couple elements of host computing platform 110 to storage device 120. In another example, I/O interfaces 103 and 123 may be arranged as a Serial Attached Small Computer System Interface (SCSI) (or simply SAS) interface to couple elements of host computing platform 110 to storage device 120. In another example, I/O interfaces 103 and 123 may be arranged as a Peripheral Component Interconnect Express (PCIe) interface to couple elements of host computing platform 110 to storage device 120. In another example, I/O interfaces 103 and 123 may be arranged as a Non-Volatile Memory Express (NVMe) interface to couple elements of host computing platform 110 to storage device 120. For this other example, communication protocols may be utilized to communicate through I/O interfaces 103 and 123 as described in industry standards or specifications (including progenies or variants) such as the Peripheral Component Interconnect (PCI) Express Base Specification, revision 3.1, published in November 2014 (“PCI Express specification” or “PCIe specification”) or later revisions, and/or the Non-Volatile Memory Express (NVMe) Specification, revision 1.2, also published in November 2014 (“NVMe specification”) or later revisions.

In some examples, system memory device(s) 112 may store information and commands which may be used by circuitry 116 for processing information. Also, as shown in FIG. 1, circuitry 116 may include a memory controller 118. Memory controller 118 may be arranged to control access to data at least temporarily stored at system memory device(s) 112 for eventual storage to storage memory device(s) 122 at storage device 120.

In some examples, storage device driver 115 may include logic and/or features to forward commands associated with one or more read or write transactions and/or read or write operations originating from system software 117. For example, storage device driver 115 may forward commands associated with write transactions such that data may be caused to be stored to storage memory device(s) 122 at storage device 120. More specifically, storage device driver 115 can enable communication of the write operations from system software 117 at computing platform 110 to storage controller 124. For example, storage device driver 115 may forward commands associated with read transactions such that data may be caused to be retrieved from storage memory device(s) 122 at storage device 120. More specifically, storage device driver 115 can enable communication of the read operations from system software 117 at computing platform 110 to storage controller 124.

System Memory device(s) 112 may include one or more chips or dies having volatile types of memory such RAM, D-RAM, DDR SDRAM, SRAM, T-RAM or Z-RAM. However, examples are not limited in this manner, and in some instances, system memory device(s) 112 may include non-volatile types of memory, including, but not limited to, NAND flash memory, NOR flash memory, 3-D cross-point memory (3D XPoint™), ferroelectric memory, SONOS memory, ferroelectric polymer memory, FeTRAM, FeRAM, ovonic memory, nanowire, EEPROM, phase change memory, memristors or STT-MRAM.

Persistent memory 119 may include one or more chips or dies having non-volatile types of memory, including, but not limited to, NAND flash memory, NOR flash memory, 3-D cross-point memory (3D XPoint™), ferroelectric memory, SONOS memory, ferroelectric polymer memory, FeTRAM, FeRAM, ovonic memory, nanowire, EEPROM, phase change memory, memristors or STT-MRAM.

According to some examples, host computing platform 110 may include, but is not limited to, a server, a server array or server farm, a web server, a network server, an Internet server, a work station, a mini-computer, a main frame computer, a supercomputer, a network appliance, a web appliance, a distributed computing system, a personal computer, a tablet computer, a smart phone, multiprocessor systems, processor-based systems, or combination thereof.

Data received by storage controller 124 may be encoded prior to sending of the data to storage memory device(s) or memory 126. When storage controller 124 receives a write transaction request, storage controller 124 may use error correcting code (ECC) write component 128 to encode the data and write the encoded data to storage memory device 122. In another embodiment, storage controller 124 may use ECC write component 128 to encode data stored in memory 126. In embodiments, ECC write component 128 uses a known LDPC code.

When storage controller receives a read transaction request, or otherwise desires to retrieve encoded data from storage memory device 122 or memory 126, storage controller 124 may use ECC read component 130 to decode the encoded data in order to access the data. Specifically, ECC read component 130 may use decoder 132 and asymmetric estimation unit (AEU) 134 to decode the encoded data. In an embodiment, decoder 132 may be a LDPC min-sum decoder.

LDPC decoders, like the min-sum, sum-product, belief-propagation decoders, etc., make use of the soft information of the read bits (variable nodes) to improve the decoder performance. This information is provided to the decoder as log-likelihood ratios (LLRs) of the input codeword bits.

In a binary symmetric channel, the cross-over probabilities (raw bit error rate (RBER)) of 1's and 0's are the same; meaning, the probabilities of 1's getting flipped to 0's, and 0's getting flipped to 1's are the same. However, storage memory device 122 or memory 126 may behave as a binary asymmetric channel, which could flip 1's to 0's and 0's to 1's with unequal probabilities. Estimating these cross-over probabilities (hence LLRs) and leveraging this information in LDPC decoder 132 according to embodiments of the present invention enables an improved min-sum decoding performance. Note that the RBER and the LLR for a given symbol ‘y’ are related as:

$$LLR ( y ) = ln ( \frac{1 - rber ( y )}{rber ( y )} )$$

For a hard read of data from storage memory device 122 or memory 126, there can be two possible symbol values: 0 and 1, thus:

$$LLR ( 0 ) = ln ( \frac{1 - rber ( 0 )}{rber ( 0 )} ) and$$

$$LLR ( 1 ) = ln ( \frac{1 - rber ( 1 )}{rber ( 1 )} )$$

Note that for a soft read of data from storage memory device 122 or memory 126, for example a 3-strobe read, the number of buckets (which is same as the number of unique symbols) is 4, and the RBER of each bucket needs to be estimated to generate the LLRs of each bucket, wherein a bucket is a grouping of bits that belong to a given symbol in a codeword.

Channel:

Consider a binary asymmetric channel with RBER(0) and RBER(1), which are the raw-bit error rates for the bits 0 and 1 respectively. In embodiments the binary asymmetric channel couples storage memory device 122 with ECC read component 130, and memory 126 with ECC read component 130. A process for RBER estimation (estimation of RBER=[RBER(0) RBER(1)]) for the hard read case is shown and then extended to the soft read case. A hard read case (e.g., hard decision decoding) has only one strobe for obtaining the value of a bit from a memory, and includes no confidence information. A soft read case (e.g., soft decision decoding) may include three strobes, for example, to provide confidence information.

Hard Read Case:

Let the set of indices of 0's and 1's in the error-free/written codeword be S₀ and S₁, respectively. Let the set of indices of 0's and 1's in the noisy/read codeword be S′₀ and S′₁, respectively. Then, the number of bits that flipped from 0's in the error-free codeword to become 1's in the noisy codeword is given by S₀∩S′₁. Similarly, the number of bits that flipped from 1's in the error-free codeword to become 0's in the noisy codeword is given by S₁∩S′₀. Thus, the RBERs of 1's and 0's are given by

$$\begin{matrix}RBER ( 0 ) = {p}_{1 \to 0} = \frac{n ( {S}_{1} ⋂ {S}_{0}^{′} )}{n ( {S}_{1} )} = \frac{n ( {S}_{1} ⋂ {S}_{0}^{′} )}{n ( ( {S}_{1}^{′} \backslash {S}_{0} ⋂ {S}_{1}^{′} ) ⋃ ( {S}_{1} ⋂ {S}_{0}^{′} ) )} \approx \frac{n ( {S}_{1} ⋂ {S}_{0}^{′} )}{n ( {S}_{1}^{′} )} & ( 1 a ) \\ RBER ( 1 ) = {p}_{0 \to 1} = \frac{n ( {S}_{0} ⋂ {S}_{1}^{′} )}{n ( {S}_{0} )} = \frac{n ( {S}_{0} ⋂ {S}_{1}^{′} )}{n ( ( {S}_{0}^{′} \backslash {S}_{1} ⋂ {S}_{0}^{′} ) ⋃ ( {S}_{0} ⋂ {S}_{1}^{′} ) )} \approx \frac{n ( {S}_{0} ⋂ {S}_{1}^{′} )}{n ( {S}_{0}^{′} )} & ( 1 b )\end{matrix}$$

Correcting a noisy codeword involves iteratively flipping of bits using the messages exchanged between check nodes and variable nodes. Channel estimation may be based on the premise that statistically, the majority of the flipping decisions made by the decoder is correct. Meaning, at the end of t iterations, the number of 0's in the received codeword that flipped to 1's in the partially-decoded codeword, f_{0→1}, is proportional to n(S₁∩S′₀). Similarly, the number of 1's in the received codeword that flipped to 0's in the partially-decoded codeword, f_{1→0}, is proportional to n(S₀∩S′₁). Thus, it may be postulated that

$$\frac{{f}_{1 \to 0}}{{f}_{0 \to 1}}$$

is indicative of the asymmetry, r, of the channel.

$$r = \frac{RBER ( 1 )}{RBER ( 0 )} \approx \frac{\frac{n ( {S}_{0} ⋂ {S}_{1}^{′} )}{n ( {S}_{0}^{′} )}}{\frac{n ( {S}_{1} ⋂ {S}_{0}^{′} )}{n ( {S}_{1}^{′} )}} \approx k ( {RBER}_{—} est ) \times \frac{\frac{{f}_{1 \to 0}}{n ( {S}_{0}^{′} )}}{\frac{{f}_{0 \to 1}}{n ( {S}_{1}^{′} )}} \qquad ( 2 )$$

Note that this estimation of the channel asymmetry requires k(RBER_est), which is an RBER dependent scaling factor.

Second, the value RBER_est may be obtained, which is the RBER of the two buckets combined, using the following equation

$${RBER}_{est} = round ( \frac{1}{2} - \frac{1}{2} {( 1 - 2 \times \frac{{syn}_{wt}}{no . of rows in LDPC matrix} )}^{1 \text{/} degree} ) \qquad ( 3 )$$

where, syn_{wt} is the syndrome weight of the input noisy codeword, and degree is a constant that depends on the matrix geometry.

Finally, the split RBERs are obtained using the following relation:

$$\begin{matrix}RBER ( 1 ) \approx \frac{RBER \times ( n ( {S}_{0}^{′} ) + n ( {S}_{1}^{′} ) )}{( n ( {S}_{0}^{′} ) + r . n ( {S}_{1}^{′} ) )} & ( 4 a ) \\ RBER ( 0 ) \approx \frac{RBER ( 1 )}{r} & ( 4 b )\end{matrix}$$

Soft Read Case:

the soft read case may be described using a 3-strobe read as an example. A 3-strobe read results in 4 buckets—high confidence (HC) 1 (a), low confidence (LC) 1 (b), low confidence 0 (c), and high confidence 0 (d). Here, find the number of symbols that transitioned from every bucket to the opposite sign—f_{a→0}, f_{b→0}, f_{c→1}, and f_{d→1}. Once these numbers are known, a two-step process may be followed. First, the RBERs of 1's and 0's may be estimated and then the RBERs of HC and LC buckets within 1's and 0's may be estimated.

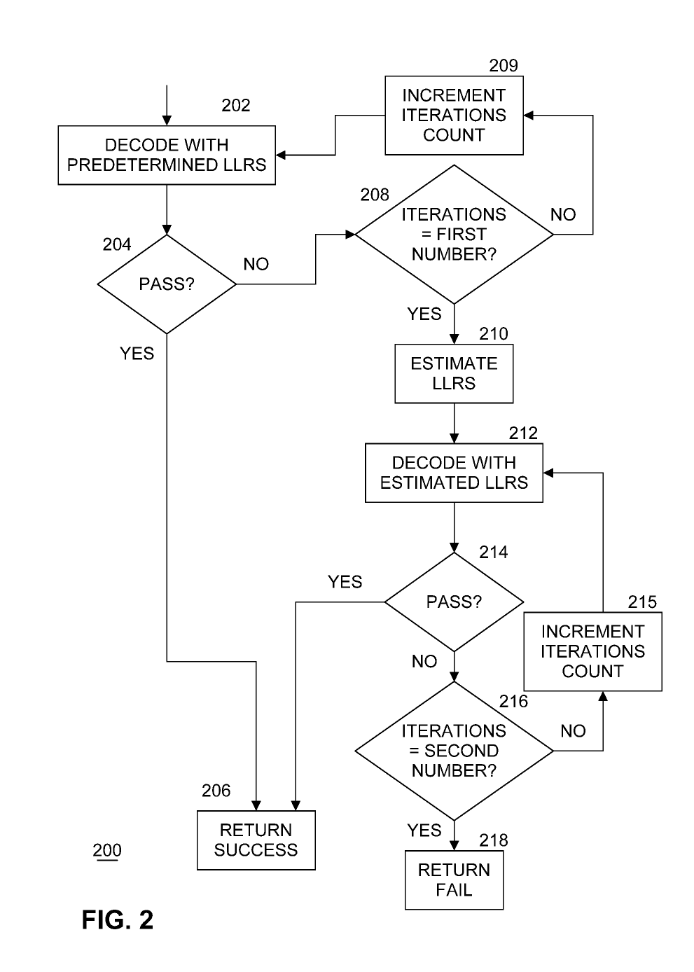

FIG. 2 illustrates an example of a logic flow for managing decoding by logic within ECC read component 130. This flow may be repeated for every codeword to be decoded by decoder 132. In an embodiment, a codeword may comprises 4K words of data being transferred over a channel. At the beginning of processing each codeword, an iteration count may be set to one. Processing of a codeword received from storage memory device 122 or memory 126 begins at block 202 where decoder 132 within ECC read component 130 operates on the codeword using a set of predetermined LLRs as input parameters. These predetermined LLRs may be known a priori as characteristics of a particular storage memory device 122 or memory 126. In an embodiment, the predetermined LLRs all have equal values, which reflect a binary symmetric channel.

If the decoding of the codeword using the predetermined LLRs passes at block 204 (that is, the decoding attempt results in correct data based on a computation of an error syndrome), a success indicator and the data may be returned at block 206. ECC read component 130 may then transfer the data as needed. If the decoding of the codeword does not pass at block 204, a check is made at block 208 to determine if the number of iterations of attempting to decode the codeword is equal to a first threshold (i.e., a first number). In examples, any number may be chosen for the first threshold as an implementation decision. If not, the count of the number of iterations of attempting to decode the codeword may be incremented at block 209, and processing continues with another decoding attempt at block 202. If the first threshold is reached at block 208, processing continues with block 210.

According to embodiments of the present invention, instead of further using predetermined LLRs for subsequent iterations, ECC read component 130 may use logic within asymmetry estimation unit (AEU) 134 to observe residual symbol flips and estimate the channel asymmetry as evidenced by unequal LLRs at block 210 to now use as input parameters for decoder 132. In embodiments, AEU 134 computes LLRs as shown above in equations 4(a) and 4(b) detailed above. In at least one embodiment, AEU 134 may be implemented as logic in circuitry to perform calculations of equations 4(a) and 4(b). These estimated LLRs may be used by decoder 132 at block 212 to attempt to decode the codeword.

If the decoding of the codeword using the estimated LLRs passes at block 214 (that is, the decoding attempt results in correct data based on a computation of an error syndrome), a success indicator and the data may be returned at block 206. ECC read component 130 may then transfer the data as needed. If the decoding of the codeword does not pass at block 214, a check is made at block 216 to determine if the number of iterations of attempting to decode the codeword is equal to a second threshold (i.e., a second number). In examples, any number may be chosen for the second threshold as an implementation decision, as long as the second threshold is larger than the first threshold. If not, the count of the number of iterations of attempting to decode the codeword may be incremented at block 215, and processing continues with another decoding attempt at block 212. If the second threshold is reached at block 216, processing continues with block 218, where a failure indication may be returned. The steps of FIG. 2 may be repeated for the next codeword until all codewords of the requested data have been processed.

It is well-known that channel asymmetry is a major cause of error performance loss, especially during the end-of-life scenarios. Embodiments of the present invention provide a method of operating at close-to-optimal performance even in the presence of asymmetry. This not only improves error performance of products including these embodiments, but also reduces the time to market. Embodiments of the present invention may recover approximately 85% of the RBER that is lost due to asymmetry.

Included herein is a set of logic flows representative of example methodologies for performing novel aspects of the disclosed architecture. While, for purposes of simplicity of explanation, the one or more methodologies shown herein are shown and described as a series of acts, those skilled in the art will understand and appreciate that the methodologies are not limited by the order of acts. Some acts may, in accordance therewith, occur in a different order and/or concurrently with other acts from that shown and described herein. For example, those skilled in the art will understand and appreciate that a methodology could alternatively be represented as a series of interrelated states or events, such as in a state diagram. Moreover, not all acts illustrated in a methodology may be required for a novel implementation.

A logic flow may be implemented in software, firmware, and/or hardware. In software and firmware embodiments, a logic flow may be implemented by computer executable instructions stored on at least one non-transitory computer readable medium or machine readable medium, such as an optical, magnetic or semiconductor storage. The embodiments are not limited in this context.

According to some examples, storage controller 124 of FIG. 1, including ECC read component 130, may execute processing operations or logic for the steps shown in FIG. 2. Storage controller 124 may include various hardware elements, software elements, or a combination of both. Examples of hardware elements may include devices, logic devices, components, processors, microprocessors, circuits, processor circuits, circuit elements (e.g., transistors, resistors, capacitors, inductors, and so forth), integrated circuits, ASIC, programmable logic devices (PLD), digital signal processors (DSP), FPGA/programmable logic, memory units, logic gates, registers, semiconductor device, chips, microchips, chip sets, and so forth. Examples of software elements may include software components, programs, applications, computer programs, application programs, device drivers, system programs, software development programs, operating system software, middleware, firmware, software components, routines, subroutines, functions, methods, procedures, software interfaces, application program interfaces (API), instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given example.

The components and features of host computing platform 110 and storage device 120 may be implemented using any combination of discrete circuitry, ASICs, logic gates and/or single chip architectures. Further, the features of host computing platform 110 and storage device 120 may be implemented using microcontrollers, programmable logic arrays and/or microprocessors or any combination of the foregoing where suitably appropriate. It is noted that hardware, firmware and/or software elements may be collectively or individually referred to herein as “logic”, “circuit” or “circuitry.”

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, but yet still co-operate or interact with each other.

It is emphasized that the Abstract of the Disclosure is provided to comply with 37 C.F.R. Section 1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single example for the purpose of streamlining the disclosure. This method of disclosure is not to be interpreted as reflecting an intention that the claimed examples require more features than are expressly recited in each claim. Rather, as the following claims reflect, inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. An apparatus coupled to a memory, the apparatus comprising:
circuitry; and
logic for execution by the circuitry to:
decode an encoded codeword of data received from a memory using predetermined log-likelihood ratios (LLRs) to produce a decoded codeword;
return the decoded codeword when the decoded codeword is correct;
repeat the decoding using the predetermined LLRs when the decoded codeword is not correct, up to a first number of times when the decoded codeword is not correct; and
when a correct decoded codeword is not produced:
estimate the LLRs;
decode the encoded codeword using the estimated LLRs to produce a decoded codeword;
return the decoded codeword when the decoded codeword is correct; and
repeat the decoding using estimated LLRs when the decoded codeword is not correct, up to a second number of times when the decoded codeword is not correct.

2. The apparatus of claim 1, wherein the apparatus is coupled to the memory over a binary asymmetric channel.

3. The apparatus of claim 2, wherein the logic to estimate the LLRs includes logic to estimate the LLRs using a raw bit error rate (RBER) of a 0 and a RBER of a 1 for bits in the codeword.

4. The apparatus of claim 3, wherein
$$RBER ( 1 ) \approx \frac{RBER \times ( n ( {S}_{0}^{′} ) + n ( {S}_{1}^{′} ) )}{( n ( {S}_{0}^{′} ) + r . n ( {S}_{1}^{′} ) )}$$
$$RBER ( 0 ) \approx \frac{RBER ( 1 )}{r}$$
where S′₀ and S′₁ is a set of indices of 0's and 1's in the codeword, respectively, r is an asymmetry of the channel, and n is a number of bits in the codeword that flipped.

5. The apparatus of claim 4, wherein the logic to estimate the LLRs includes logic to estimate the LLRs as
$$LLR ( y ) = ln ( \frac{1 - rber ( y )}{rber ( y )} )$$
where y is a given symbol in a set of unique symbols in the codeword.

6. A method comprising:
decoding an encoded codeword of data received from a memory using predetermined log-likelihood ratios (LLRs) to produce a decoded codeword;
returning the decoded codeword when the decoded codeword is correct;
repeating the decoding using the predetermined LLRs when the decoded codeword is not correct, up to a first number of times when the decoded codeword is not correct; and
when a correct decoded codeword is not produced:
estimating the LLRs;
decoding the encoded codeword using the estimated LLRs to produce a decoded codeword;
returning the decoded codeword when the decoded codeword is correct; and
repeating the decoding using estimated LLRs when the decoded codeword is not correct, up to a second number of times when the decoded codeword is not correct.

7. The method of claim 6, wherein the apparatus is coupled to the memory over a binary asymmetric channel.

8. The method of claim 7, wherein estimating the LLRs includes estimating the LLRs using a raw bit error rate (RBER) of a 0 and a RBER of a 1 for bits in the codeword.

9. The method of claim 8, wherein
$$RBER ( 1 ) \approx \frac{RBER \times ( n ( {S}_{0}^{′} ) + n ( {S}_{1}^{′} ) )}{( n ( {S}_{0}^{′} ) + r . n ( {S}_{1}^{′} ) )}$$
$$RBER ( 0 ) \approx \frac{RBER ( 1 )}{r}$$
where S′₀ and S′₁ is a set of indices of 0's and 1's in the codeword, respectively, r is an asymmetry of the channel, and n is a number of bits in the codeword that flipped.

10. The method of claim 9, wherein estimating the LLRs includes estimating the LLRs as
$$LLR ( y ) = ln ( \frac{1 - rber ( y )}{rber ( y )} )$$
where y is a given symbol in a set of unique symbols in the codeword.

11. A storage device comprising:
a memory;
a binary asymmetric channel coupled to the memory;
circuitry coupled to the binary asymmetric channel; and
logic for execution by the circuitry to:
decode an encoded codeword of data received from the memory over the binary asymmetric channel using predetermined log-likelihood ratios (LLRs) to produce a decoded codeword;
return the decoded codeword when the decoded codeword is correct;
repeat the decoding using the predetermined LLRs when the decoded codeword is not correct, up to a first number of times when the decoded codeword is not correct; and
when a correct decoded codeword is not produced:
estimate the LLRs;
decode the encoded codeword using the estimated LLRs to produce a decoded codeword;
return the decoded codeword when the decoded codeword is correct; and
repeat the decoding using estimated LLRs when the decoded codeword is not correct, up to a second number of times when the decoded codeword is not correct.

12. The storage device of claim 11, wherein the logic to estimate the LLRs includes logic to estimate the LLRs using a raw bit error rate (RBER) of a 0 and a RBER of a 1 for bits in the codeword.

13. The storage device of claim 12, wherein
$$RBER ( 1 ) \approx \frac{RBER \times ( n ( {S}_{0}^{′} ) + n ( {S}_{1}^{′} ) )}{( n ( {S}_{0}^{′} ) + r . n ( {S}_{1}^{′} ) )}$$
$$RBER ( 0 ) \approx \frac{RBER ( 1 )}{r}$$
where S′₀ and S′₁ is a set of indices of 0's and 1's in the codeword, respectively, r is an asymmetry of the channel, and n is a number of bits in the codeword that flipped.

14. The storage device of claim 13, wherein the logic to estimate the LLRs includes logic to estimate the LLRs as
$$LLR ( y ) = ln ( \frac{1 - rber ( y )}{rber ( y )} )$$
where y is a given symbol in a set of unique symbols in the codeword.

15. The storage device of claim 11, wherein the memory comprises a NAND memory.

16. The storage device of claim 11, wherein the memory comprises a three-dimensional cross point memory.

17. The storage device of claim 11, wherein the logic comprises a low-density parity check (LDPC) min-sum decoder.
